(19) United States
(12) Patent Application Publication
(10) Pub. No.: US 2007/0205835 A1
(43) Pub. Date: Sep. 6, 2007

(54) Robust locking/tuning in a multi-rate, multi-range phase locked loop

(76) Inventors: Eric Iozsef, Toronto (CA); Mohammad H. Shakiba, Richmond Hill (CA); Eliyahu D. Zamir, Thomhill (CA); Hossein Hashemi, Montreal (CA); Fahim Adam Hasham, Unionville (CA); Mathew Johnson, Waterdown (CA)

Correspondence Address: PATENT GROUP 2N;JONES DAY, NORTH POINT, 901 LAKESIDE AVENUE, CLEVELAND, OH, 44114, US

(21) Appl. No.: 11/649,096

(22) Filed: Jan. 3, 2007

Related U.S. Application Data
(60) Provisional application No. 60/755,757, filed on Jan. 3, 2006.

(51) Int. Cl. H03L 7/00

(52) U.S. Cl. 331/16

(57) ABSTRACT

Systems and methods for tuning a phase locked loop (PLL) having a segmented voltage controlled oscillator (VCO) to an input frequency are provided. The PLL is reset and its VCO is coarse tuned until the input frequency is within a first predetermined threshold of the VCO center frequency. The input frequency is then compared to a clock reference signal to determine whether the input frequency has stabilized. After the input frequency has stabilized, the input frequency is continuously monitored by comparing it to the clock reference signal to determine whether the input frequency is varying, and if the input frequency is varying by more than a second predetermined threshold, then the PLL is reset.

### CROSS-REFERENCE TO RELATED APPLICATIONS

This application claims priority to U.S. Provisional Application Ser. No. 60/755,757, filed on Jan. 3, 2006, and titled “Robust Locking/Tuning in a Multi-Rate, Multi-Range Phase Locked Loop.” The entirety of this prior application is hereby incorporated by reference into this patent application.

### BACKGROUND

In order to be able to lock to a wide and continuous range of frequencies, phase locked loops (PLLs) typically utilize a wide-tuning voltage controlled oscillator (VCO) and/or require multiple dividers in the feedback path. Wide tuning VCOs, however, exhibit high gain by necessity and therefore are susceptible to higher jitter generation.

To reduce the VCO gain, and therefore reduce the jitter generation due to noise on the control voltage, the VCO is often “broken up” into multiple overlapping frequency tuning ranges—the so-called segmented VCO. In the segmented VCO, a tuning mechanism is used to select a VCO “coarse tune” that generates a frequency that most closely matches the input frequency. A “fine tune” mechanism is then typically used to further adjust the VCO frequency until it exactly matches the input frequency and phase. By using multiple overlapping coarse tunes, the gain of the segmented VCO can be reduced and therefore the susceptibility to noise on the control voltage is also reduced.

The use of a segmented VCO having multiple coarse tunes, however, presents several challenges in the design of a phase locked loop. For example, frequency and phase lock should be maintained on the selected coarse tune in an acceptable frequency band over temperature and supply voltage variations. In addition, frequency and phase lock should be achieved on the correct coarse tune (allowing for frequency variation of the VCO over temperature) even under extreme input conditions where the input frequency to the phase locked loop varies at start-up or where the input frequency changes in an unpredictable manner when the input is switched from frequency A to frequency B (as often happens with frequency synthesizer type sources). And finally, frequency and phase lock should be achieved on the correct coarse tune even when the input frequency changes by incrementally small amounts from an initial lock condition—i.e. there should be no frequency “crawl” beyond the allowable frequency range.

### SUMMARY

Systems and methods for tuning a phase locked loop (PLL) having a segmented voltage controlled oscillator (VCO) to an input frequency are provided. The PLL is reset and its VCO is coarse tuned until the input frequency is within a first predetermined threshold of the VCO center frequency. The input frequency is then compared to a clock reference signal to determine whether the input frequency has stabilized. After the input frequency has stabilized, the input frequency is continuously monitored by comparing it to the clock reference signal to determine whether the input frequency is varying, and if the input frequency is varying by more than a second predetermined threshold, then the PLL is reset.

### BRIEF DESCRIPTION OF THE DRAWINGS

FIG. 1 is a voltage versus frequency plot showing a single VCO coarse tune in a segmented VCO at two temperatures;

FIG. 2 is a voltage versus frequency plot describing a “midtrack” condition of the segmented VCO;

FIG. 3 is a voltage versus frequency plot describing an “overtrack” condition of the segmented VCO;

FIG. 4 is a block diagram of an example phase locked loop having robust locking/tuning circuitry;

FIG. 5 is a flow chart of an example methodology for locking and tracking phase and frequency in a multi-rate phase locked loop having a segmented VCO and a crystal oscillator reference; and

FIG. 6 is a flow chart of an example methodology for locking and tracking phase and frequency in a multi-rate phase locked loop without a crystal oscillator.

### DETAILED DESCRIPTION

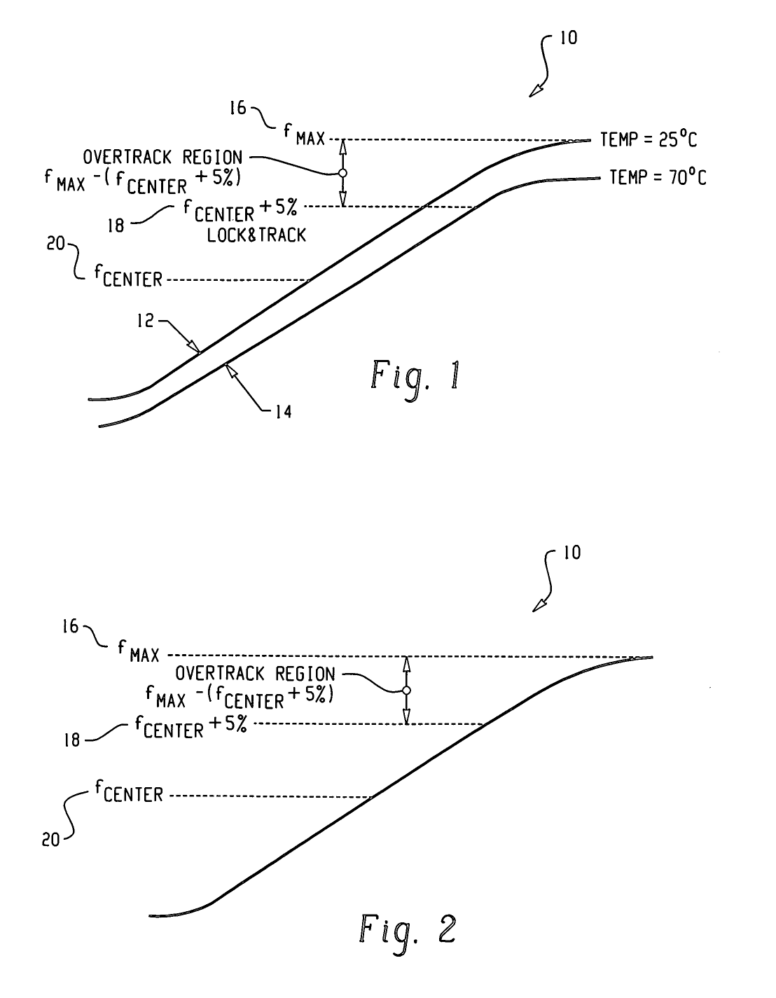

FIG. 1 is voltage versus frequency plot 10 showing a single VCO coarse tune in a segmented VCO at two temperature curves 12, 14. The upper curve 12 shows the voltage versus frequency at 25C, and the bottom curve shows the same response at 70C. As the temperature changes, the entire curve moves with respect to frequency. Under “normal” conditions the VCO frequency is initially at fcenter 20. The maximum VCO frequency is fmax 16, as shown at the top of the plot, and the minimum frequency is fmin, which is at the very bottom of the plot.

In the example implementation of a robust tune-controlled PLL discussed herein, if the input frequency to the PLL is within +/−5% of fcenter, or some other predetermined coarse tuning threshold value, then the VCO control is released and allowed to vary so that the PLL can lock to the input frequency. This is referred to as the “lock and track” region and extends to 5% above and below 18 the center frequency fcenter 20. If the input frequency is not within this lock and track region defined by the coarse tuning threshold value, then the system selects another VCO segment and compares that segment's center frequency to the input frequency to determine if the input frequency is within the locking region. The remaining frequency range beyond +/−5% of fcenter up to fmax is referred to as the “midtrack” region, and is provided to cover the temperature and supply variations of the VCO. This region is defined by the frequency band fmax−(fcenter+5%) on either side of the locking and tracking region.

FIG. 2 describes the “midtrack” condition of the segmented VCO in which the input frequency is within 5% of fcenter at the onset of locking, but then it gradually increases to the midtrack section, beyond the 5% allowable range. This can occur, for example, when the input frequency changes from frequency A to frequency B, but the transition time between the two frequencies is relatively long. In this circumstance, the PLL may not lose lock, thereby putting the PLL into the reset mode, but instead maintains lock and tracks the input frequency into the midtrack section as the input frequency slowly changes from frequency A to frequency B. The PLL will then lock to frequency B outside of the +/−5% range and into the midtrack region. It may even lock very closely to fmax. This locking action away from the center frequency of the VCO compromises its temperature margin. The tuning control circuitry and methodology disclosed herein prevents midtrack locking by continuously monitoring and resetting the PLL if the input frequency strays outside of the +/−5% frequency margin, even when the input frequency is varying slowly from one frequency set point to another.

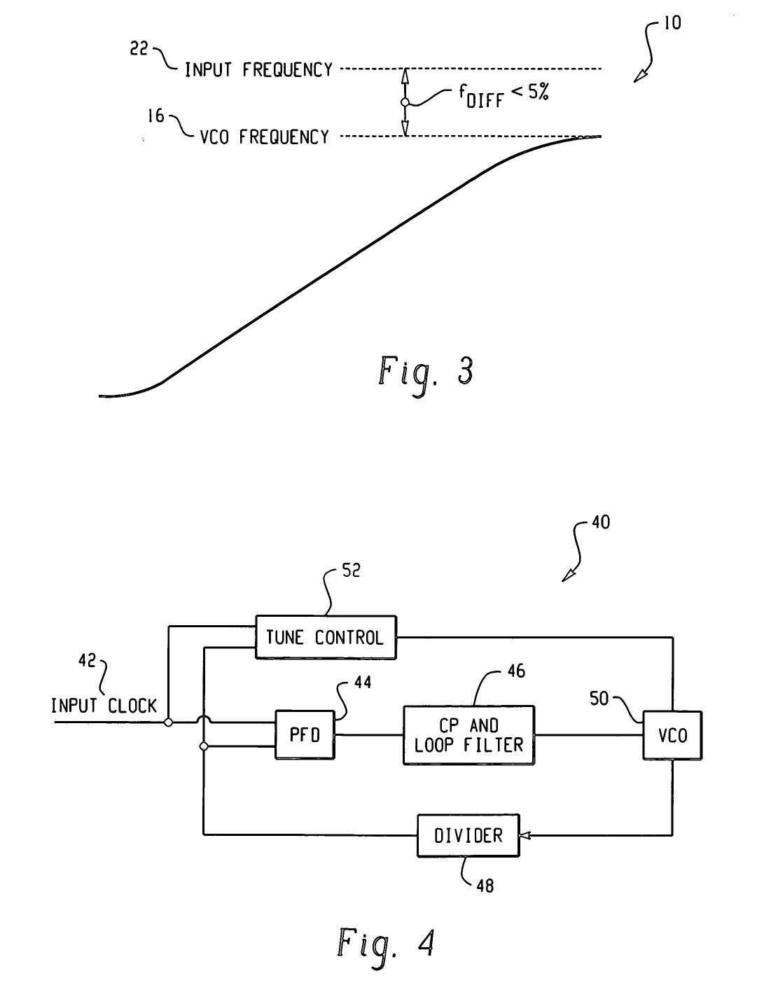

FIG. 3 describes the “overtrack” condition of the segmented VCO in which the input frequency is within 5% of center at the onset of locking but then it gradually increases beyond the range of the VCO. This is an extension of the “midtrack” problem discussed above in relation to FIG. 2, but is even worse because now the input frequency has slowly varied beyond the range of the VCO. If the final input frequency is still within 5% of the maximum/minimum frequency of the VCO, then the coarse tuning function of the VCO is not incremented and the PLL remains unlocked without any means of recovering.

FIG. 4 is a block diagram of an example phase locked loop 40 having robust locking/tuning circuitry for handling the various input frequency conditions discussed above. The loop includes a multi-range voltage controlled oscillator 50. Multi-range VCOs have been used to achieve the high tuning range required in systems that are intended to support a wide variety of input clock 42 frequencies. Accommodating the high tuning range in a single range VCO is possible, however, the performance of the PLL becomes susceptible to noise due to the high VCO gain required to cover the entire range in one segment. Thus, as shown in FIG. 4, in addition to the classical architecture of the PLL, which includes a phase frequency detector 44 (PFD), a charge pump (CP) and loop filter 46, the VCO 50, and a feedback divider 48, the present invention adds a robust locking/tuning control circuit 52 that ensures that for every given input frequency 42, within a particular limit, the proper range of the segmented VCO is selected and maintained.

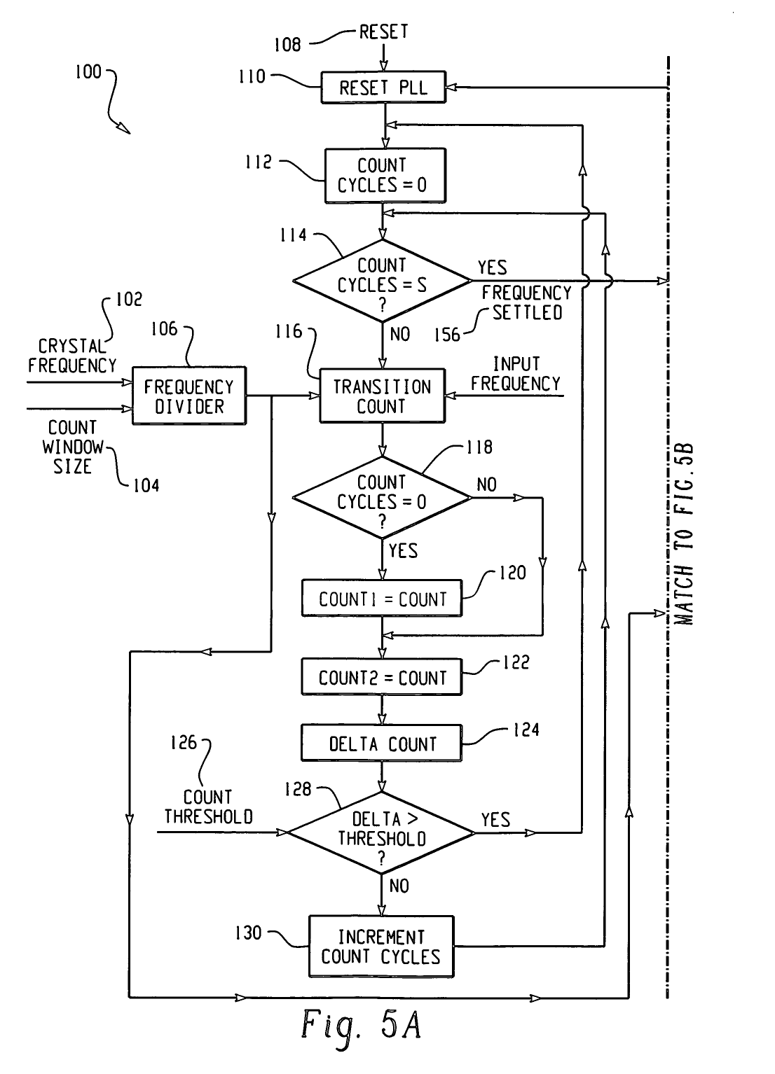

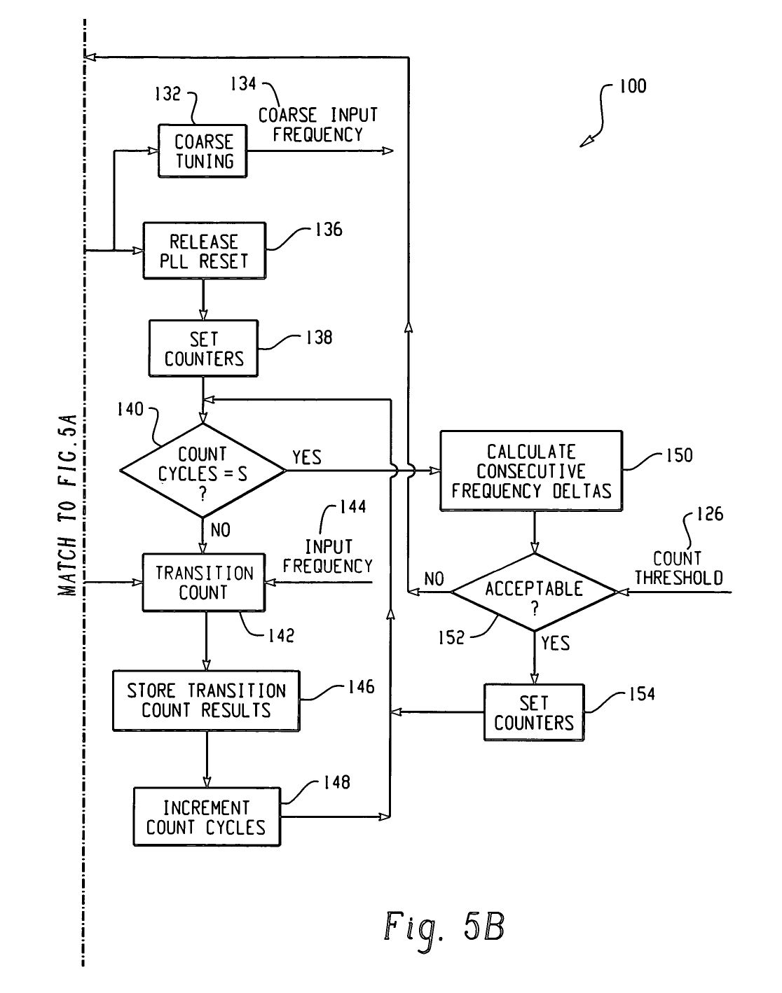

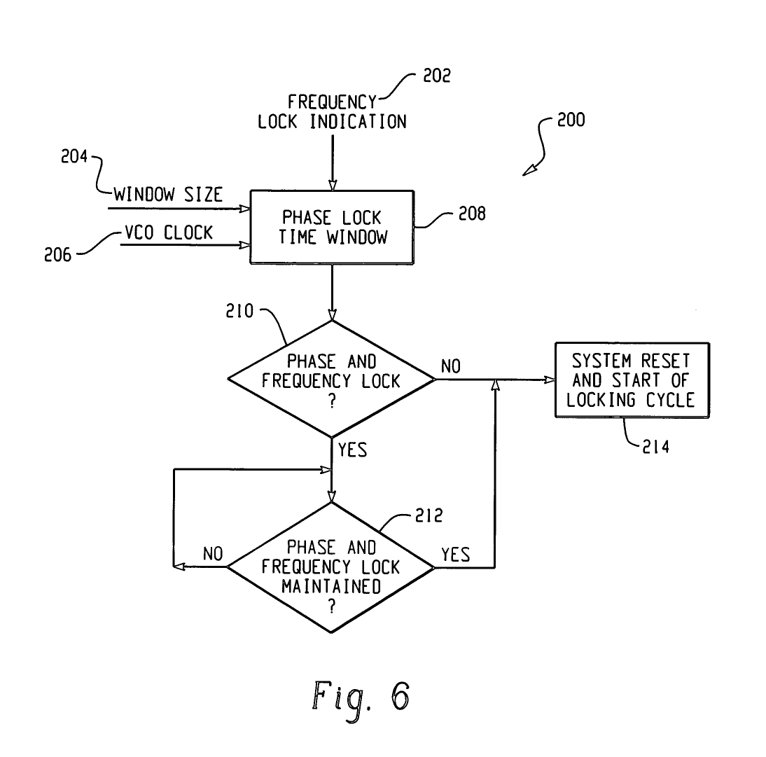

The methodology and implementation of the locking/tuning control circuit 52 is described in more detail below in reference to FIGS. 5 and 6, which provide alternative functional implementations of the circuitry provided in this block 52. Physically, the tuning control circuit 52 embodies a finite state machine that compares the input frequency 42 with the center frequency of each range of the segmented VCO 50 and selects the range that accommodates the input frequency 42 within a set limit of that particular center frequency. This is the coarse tuning operation. Having selected the proper coarse tuning segment, the VCO is then “released” from its center frequency and normal operation of the PLL 40 begins until phase and frequency lock are achieved. This is the fine tuning operation. The locking/tuning control circuitry 52 continues to operate during fine tuning of the PLL to ensure that the selected VCO setting is best-suited for the operating conditions of the PLL 40.

The tuning control circuit 52 also provides a solution to several other problems that exist with PLLs having segmented VCOs. Segmentation of the VCO frequencies introduces the problem of handling switchovers from one range to another and ensuring that once a VCO range is selected it can absorb any variations in the VCO characteristic arising from changes in the operating conditions of the circuit, such as supply voltage and temperature variations.

Another challenge associated with employing a multi-range VCO in a PLL relates to frequency tracking of the system before the input frequency 42 has stabilized. There are two aspects to this problem. The first aspect is the transition in the input frequency 42 as it changes from one frequency to another prior to locking of the loop. If this transition is not fast enough, then the tuning control circuitry 52 may coarse tune the VCO 50 before the input frequency has settled to its final value. In this case, the wrong VCO range may be selected and the PLL may not be able to achieve phase or frequency lock.

The second aspect is the subsequent changing of the input frequency after the PLL has locked. Here, when the input frequency 42 changes, the PLL 40 loses lock and enables the coarse tuning operation once again. But if the input frequency 42 starts to change very slowly to a new, and possibly close frequency, so that the PLL 40 does not lose lock, then the coarse tuning mechanism does not take place and the state of the tune control circuitry does not change. In this situation, and depending in part on the amount of change in the input frequency, the existing VCO 50 range may not be able to maintain the lock anymore and the PLL may lose lock altogether. Moreover, even if phase and frequency lock are achieved at the second frequency, the VCO range may not be wide enough to accommodate the variations in the VCO as a result of changes in the operating conditions of the circuitry, such as power supply and temperature.

The tuning control circuitry 52, as functionally described in more detail below, provides a solution to these challenges in employing a segmented VCO 50. The finite state machine of the turning control circuitry 52 provides several logic mechanisms that when used in conjunction with each other allow the PLL 40 to lock to an incoming frequency 42 within an allowable range of the center frequency of the VCO 50 on a given coarse tune. These logic mechanisms are able to detect small changes in input frequency 42, thus preventing the PLL 40 from tracking changes in input frequency beyond the allowable locking range of the VCO 50. This allows the VCO 50 to retain its built-in margin over temperature and power supply variations.

In one embodiment, the tuning control circuit 52 includes a first circuit to compare the center frequency of the VCO 50 (on a given coarse tune) to the input frequency 42. If the input frequency 42 is more than 5% different (the 5% being user selectable) from the VCO center frequency, then the coarse tune and/or divider 48 is incremented or decremented (unidirectional or bi-directional counter) by 1. If the input frequency 42 is less than 5% away from the VCO 50 center frequency, then the VCO 50 is “released” to try and lock to the input frequency by removing the short from the differential loop filter 46.

In this embodiment of the tune control block 52, a second circuit, operating in parallel with the first circuit, is used to detect when the input frequency 42 has stabilized and to determine when the input frequency 42 has changed by a small amount (preferably<1%, but also user selectable). This is accomplished by comparing the input frequency to a stable clock reference, such as a crystal. In so doing, the input frequency 42 is first compared to the crystal frequency. The value of the input frequency 42 is stored. The input frequency 42 is then measured three more times, for example, over a time period specified by the user. If the three consecutive frequency measurements match the original frequency measurement within a tolerance value, then the input frequency is considered to have “settled.”

During the time that these frequency measurements are made on the input clock 42, the PLL 40 is kept in its reset mode, meaning that it is not allowed to phase or frequency lock by forcing the PLL loop filter 46 voltage to the mid-point, and therefore the VCO at mid-frequency (for the selected coarse tune). The VCO is, however, allowed to change coarse tunes during this reset time due to the simultaneous operation of the first circuit described above.

After the second circuit determines that the input frequency 42 has “settled,” the reset to the PLL 40 is deactivated, and the loop is then free to both phase and frequency lock to the input signal 42. During this phase of operation, the second circuit then continuously monitors the input frequency 42 by comparing it to the crystal frequency. If the input frequency 42 differs from the original “settled” input frequency by more than a threshold, such as a programmable threshold, then the circuitry determines that the input frequency 42 has changed and the PLL 40 will be placed back into the reset mode with the locking cycle beginning anew as described above. This continuous monitoring operation ensures that when there is an input frequency change, the PLL 40 will not phase and frequency track the input frequency outside of the normal operating bounds of the given coarse tune of the VCO 50. If these bounds are exceeded, then the operating margin of the PLL/VCO over temperature or supply voltage variations is reduced and the PLL could lose lock.

FIG. 5 is a flow chart 100 of an example methodology for locking and tracking phase and frequency in a multi-rate phase locked loop having a segmented VCO and a crystal oscillator reference. This methodology may be implemented by tuning control circuitry 52 as shown in FIG. 4 in the form of a finite state machine, or it may be implemented in software or some other form of circuitry. The method begins at step 110, when some form of reset signal causes the PLL to be put into the reset mode. This can occur upon power up of the PLL circuitry, or when the input frequency changes and the VCO requires coarse tuning. During this reset period, the “first circuit” of the tuning control circuit 52 described above selects a particular VCO frequency segment and compares the input frequency to that segment's center frequency (fcenter) in order to determine whether the input frequency is within some predetermined threshold percentage of the center frequency, such as +/−5% of the center frequency.

Having “reset” the PLL, the methodology of FIG. 5 then enters two phases, a first phase as shown in FIG. 5A in which the tuning control circuit analyzes the input frequency and compares it against a crystal oscillator in order to detect when the input frequency has settled or stabilized, and a second phase as shown in FIG. 5B in which the tuning control circuit continuously monitors the settled input frequency to detect whether it is changing beyond a second predetermined threshold percentage of its initial settled value. If the input frequency changes beyond this threshold percentage, such as 1 or 2% of its initial settled value, then the PLL is put back into the reset mode and the coarse tuning operation begins again. In this manner the midtrack and overtrack conditions discussed above in relation to FIGS. 2 and 3 are avoided.

Turning then to the first phase of the methodology shown in FIG. 5, a count cycles variable is initialized at step 112. This variable indicates how many times the method has checked the input frequency to determine if it has settled out. At step 114 the count cycles variable is compared to a constant S. This constant controls the number of times the method should check the input frequency for settling and is preferably equal to 4. If the count cycles variable has reached the value S, then the input frequency has settled and control passes to steps 132 and 136 of FIG. 5B. On the initial pass, however, the determination of step 114 is negative because count cycles must be less than S, and the method proceeds to step 116.

At step 116, a transition count value is established based upon the current frequency of the input signal and also based upon a signal from frequency divider step 106, which takes as inputs a crystal frequency 102 and a count window size 104. The frequency divider step 106 generates a time window based upon the crystal frequency 102 and a user-specified count window size 104. This time window signal from the frequency divider step 106 is then used in step 116 to count the number of transitions of the input frequency.

Having established the current transition count value of the input frequency at step 116, the method then progresses to step 118 where it is determined if the count cycles variable is still set to zero, meaning that this is the first pass through the algorithm. If so, then control passes to /step 120 where a variable count1 is set equal to the transition count value. If this was not the first pass through the algorithm, then control would pass from step 118 directly to step 122, thereby bypassing step 120, in which a variable count2 is set equal to the current transition count value. The variable count1 is initialized to the first measured transition count value, and subsequent passes through the loop 112-130 set the variable count2 to the current transition count value so that count1 and count2 can be compared to determine if the input frequency is settled.

Step 124 compares count1 to count2 and determines the difference between the two count values, referred to as delta count. This differential count value is then compared at step 128 to a predetermined, and possibly user supplied, first count threshold value 126 to determine whether the difference between count1 and count2 is greater than the threshold value. This first count threshold may be set to detect some percentage change in the input frequency, such as 5% for example. Other percentage values could also be detected based upon the desired precision of the tuning control algorithm.

If the difference between count1 and count2 is greater than the threshold 126, then control passes back to step 112 and the count cycles variable is reset to zero and the settling detection loop 112-130 is restarted. If, however, the delta count value is less than the desired percentage change in the input frequency at step 128, then control passes to step 130 where the count cycles variable is incremented by 1 and the loop reverts to step 114 to check whether the algorithm has looped through the detection step S times. If so, then at step 114 the settling algorithm ends and control passes to steps 132 and 136 via the signal frequency settled 156. If not, then the next settling detection loop is executed.

After the input frequency has settled, as determined by step 114 in FIG. 5A, control of the algorithm passes to the second phase in which the PLL is released to lock to the input frequency at step 136 and the coarse input frequency 134 of the VCO is set by the coarse tuning circuit 132 discussed above. At this point in the method the continuous monitoring operation begins so as to detect changes in the input frequency after the PLL has obtained lock.

The continuous monitoring operation begins at step 138 in which counters are initialized, including the count cycles variable which is set again to zero. In step 140 the method checks whether count cycles is set to a constant S, which is preferably 4, but could be some other value. The value of S determines how many times the loop 140-148 is executed before checking to determine if the input frequency is slowly varying beyond an acceptable limit. Loop 140-148 determines a current transition count value of the input frequency 144 at step 142 using the same count window from the frequency divider step 106 in FIG. 5A. The loop then stores the transition count results in step 148 and increments the count cycles variable in step 148 before returning to the decision step 140. Assuming that S is four, then this loop 140-148 will be repeated four times and then control will pass to step 150.

At step 150 the methodology calculates consecutive frequency deltas based upon the stored transition count results from step 146. These consecutive frequency deltas provide a measure of the frequency movement of the input frequency 144. In step 152, the frequency deltas are compared against a second count threshold 126 to determine whether the calculated frequency deltas are within acceptable limits, such as 1% of the input frequency. Although 1% is the preferred allowable delta of the input frequency to maintain lock within the “lock and track” region and to prevent movement into the “midtrack” region, other percentages are also possible. If the frequency deltas are acceptable, meaning that the input frequency has not varied by more than the second count threshold 126, then the counters are reset at step 154 and the continuous monitoring loop 140-148 is repeated. If, however, the frequency deltas are beyond the second count threshold 126 at step 152, then control reverts back to the first phase of the algorithm to step 110 where the PLL is put back into the reset mode and the entire two phase method begins anew. In this manner, frequency stability of the PLL is maintained and guaranteed over variations in supply voltage or temperature, for example.

FIG. 6 is a flow chart of an example methodology 200 for locking and tracking phase and frequency in a multi-rate phase locked loop without a crystal oscillator. This methodology may be implemented in a tuning and control circuit 52 such as shown in FIG. 4. This circuit may be used as an alternative to the input frequency measurement system discussed above with reference to FIG. 5 when no crystal reference is present in the system or as a backup to the system of the first and second circuits above.

A circuit implementing the method of FIG. 6 will maintain the VCO at its center frequency as the frequency locking circuit changes coarse tunes in order to match the VCO center frequency to the input frequency within 5%. Once the frequency locking circuit determines that this has been accomplished a frequency lock indication is enabled 202 and the short across the loop filter is removed thus enabling the VCO control voltage to vary the VCO frequency away from its center frequency in order to frequency and phase lock to the input frequency. In addition, at step 208 a phase lock time window is opened based on a count of VCO transitions using a window size signal 204 and a VCO clock signal 206.

If phase lock is achieved during the phase lock time window 208, then no further action is taken, and control passes to step 212, in which the method continuously determines whether phase and frequency lock are being maintained. If, however, phase lock is not achieved after the phase lock time window 208, or if phase lock is lost (phase lock low) after step 210, then it is assumed that the input frequency has changed. The method then resets the PLL in step 214 to the first coarse tune and resets the VCO to the center frequency. The locking cycle then begins again as described with respect to the first circuit above.

Thus, as described herein, systems and methods are provided that ensure that a multi-range PLL (with a multi-coarse tune VCO) can lock onto the correct coarse tune of the VCO regardless of how the input frequency changes. The systems and methods described herein ensure correct locking over any input frequency regardless of how frequency changes, and allow for a maximum minimum temperature margin of the VCO to be maintained even as frequency changes.

The steps and the order of the steps in the methods and flowcharts described herein may be altered, modified and/or augmented and still achieve the desired outcome. Additionally, the methods, flow diagrams and structure block diagrams described herein may be implemented in the example processing devices described herein by program code comprising program instructions that are executable by the device processing subsystem. Other implementations may also be used, however, such as firmware or even appropriately designed hardware configured to carry out the methods and flow diagrams or implement the structure block diagrams described herein. Additionally, the methods, flow diagrams and structure block diagrams that describe particular methods and/or corresponding acts in support of steps and corresponding functions in support of disclosed software structures may also be implemented in software stored in a computer readable medium and equivalents thereof. The software structures may comprise source code, object code, machine code, or any other persistently or temporarily stored code that is operable to cause one or more processing systems to perform the methods described herein or realize the structures described herein.

This written description sets forth the best mode of the invention and provides examples to describe the invention and to enable a person of ordinary skill in the art to make and use the invention. This written description does not limit the invention to the precise terms set forth. Thus, while the invention has been described in detail with reference to the examples set forth above, those of ordinary skill in the art may effect alterations, modifications and variations to the examples without departing from the scope of the invention.

What is claimed is:

1. A phase locked loop circuit, comprising:
a voltage controlled oscillator;
a first circuit configured to compare, in a reset mode, the center frequency of the voltage controlled oscillator to an input frequency and to determine if the difference in frequencies is greater than a first threshold and to increment or decrement a coarse tune signal based on the comparison if the difference is greater than the first threshold and to release the voltage controlled oscillator to lock to the input frequency if the difference is less than the first threshold; and
a second circuit configured to detect when the input frequency has stabilized and to determine when the input frequency has changed by a second threshold by comparing the input frequency to a clock reference signal and upon determining that the input frequency has stabilized to deactivate the reset mode and to further compare the input frequency to the clock reference signal and reactivate the reset mode if the input frequency has changed by a third threshold.

2. The phase locked loop circuit of claim 1, wherein the first threshold is a user defined percentage of the center frequency of the voltage controlled oscillator.

3. The phase locked loop circuit of claim 2, wherein the user defined percentage is less than 5% of the center frequency of the voltage controlled oscillator.

4. The phase locked loop circuit of claim 1, further comprising:
a crystal oscillator for generating the clock reference signal.

5. The phase locked loop circuit of claim 4, further comprising:
a time window generator coupled to the crystal oscillator and a count window size for generating the clock reference signal.

6. The phase locked loop circuit of claim 1, further comprising:
a frequency settling loop circuit for comparing the input frequency to the clock reference signal at least S times, where S is greater than 2, and for resetting the loop circuit if the difference between the input frequency and the clock reference signal is greater than the second threshold.

7. The phase locked loop circuit of claim 1, wherein the second threshold is approximately the same value as the first threshold and the third threshold is substantially smaller than either the first or second thresholds.

8. The phase locked loop circuit of claim 1, wherein the second circuit continuously monitors the input frequency after stabilization and compares the input frequency to the clock reference signal to determine if it has changed by the third threshold.

9. The phase locked loop circuit of claim 8, further comprising:
a frequency delta loop circuit for determining an initial value of the input frequency and for determining at least S additional values of the input frequency over a time window; and
a frequency delta calculation circuit for analyzing the initial and additional values of the input frequency and for determining whether the input frequency has changed by the third threshold.

10. The phase locked loop circuit of claim 1, wherein the second circuit is a finite state machine.

11. A method of tuning a phase locked loop (PLL) having a segmented voltage controlled oscillator (VCO) to an input frequency, comprising:
resetting the PLL and coarse tuning the VCO until the input frequency is within a first predetermined threshold of the VCO center frequency;
comparing the input frequency to a clock reference signal to determine whether the input frequency has stabilized; and
after the input frequency has stabilized, continuously monitoring the input frequency by comparing it to the clock reference signal to determine whether the input frequency is varying, and if the input frequency is varying by more than a second predetermined threshold, then resetting the PLL.

12. The method of claim 11, further comprising:
generating the clock reference signal from a crystal oscillator.

13. The method of claim 12, further comprising:
measuring the number of transitions of the input frequency within a time window to form a transition count value; and
comparing an initial measurement of the transition count value to one or more additional measurements of the transition count value; and
if the initial transition count value is different than the one or more additional measurements of the transition count value by third predetermined threshold, then repeating the measuring ahd comparing steps until the measurements are within the third predetermined threshold thereby signifying that the input frequency has stabilized.

14. The method of claim 10, further comprising:
releasing the PLL after the input frequency has stabilized;
measuring the number of transitions of the input frequency within a time window to form a transition count value at least S times, where S is greater than 2, and storing the transition measurements; and
analyzing the transition measurements to determine whether the input frequency is varying by more than the second predetermined threshold, and if so then resetting the PLL.

15. The method of claim 14, further comprising:
repeating the measuring and analyzing steps as long as the input frequency is not varying by more than the predetermined threshold.

16. The method of claim 11, wherein the second threshold is substantially smaller than the first threshold.

17. The method of claim 11, wherein the coarse tuning step continues to operate during the comparing step.

18. A method of tuning a phase locked loop having a voltage controlled oscillator to an input frequency, comprising:
coarse tuning the VCO to the input frequency and generating a frequency lock indicator;
generating a phase lock time window;
if the PLL phase locks during the phase lock time window, then continuously monitoring the phase and frequency lock and reseting the PLL if either phase or frequency lock is lost; and
if the PLL does not phase lock during the phase lock time window then reseting the PLL.
